(19) United States
(12) Patent Application Publication
(10) Pub. No.: US 2019/0372059 A1
(43) Pub. Date: Dec. 5, 2019

(54) DISPLAY DEVICE PRODUCING METHOD, VAPOR DEPOSITION MASK AND ACTIVE MATRIX SUBSTRATE

(71) Applicant: Sharp Kabushiki Kaisha, Sakai City, Osaka (JP)

(72) Inventors: Yuhki KOBAYASHI, Sakai City (JP); Manabu NIBOSHI, Sakai City (JP); Satoshi INOUE, Sakai City (JP); Tsuyoshi INOUE, Sakai City (JP)

(21) Appl. No.: 16/067,164

(22) PCT Filed: Mar. 30, 2017
(86) PCT No.: PCT/JP2017/013351

§ 371 Date: Jun. 29, 2018

(51) Int. Cl. H01L 51/56; H01L 51/50; H01L 51/52; H01L 27/32; H05B 33/10

(52) U.S. Cl. CPC H01L 51/56; H01L 51/5036; H01L 51/5056; H01L 51/5072; H05B 33/10; H01L 51/5253; H01L 27/3211; H01L 27/3244; H01L 51/5092

(57) ABSTRACT

A layered film is formed in a display region of an active matrix substrate, and a single layer vapor deposition film is formed outside the display region of the active matrix substrate such that at least part of the single layer vapor deposition film does not overlap with a single layer vapor deposition film.

### TECHNICAL FIELD

The disclosure relates to a display device producing method, a vapor deposition mask and an active matrix substrate.

### BACKGROUND ART

Recently, various flat panel displays have been developed, and in particular, organic Electro luminescence (EL) display devices have attracted great attention as excellent flat panel displays, because the EL display devices can realize reduced power consumption, thinning, improved image quality and the like.

Steps of producing such an organic EL display device include a step of forming multiple vapor deposition films by using a vapor deposition mask, and when film thickness variation and film formation positional offset are generated in the step of forming the vapor deposition films, such generation of film thickness variation and film formation positional offset problematically leads to quality defects of the organic EL display device.

Accordingly, numerous attempts to improve the precision of openings of vapor deposition masks have been made. For example, PTLs 1 to 5 each describe dummy openings provided in a vapor deposition mask to improve the precision of openings of the vapor deposition mask.

### CITATION LIST

### Patent Literature

PTL 1: JP 2004-185832 A (published Jul. 2, 2004)

PTL 2: JP 2004-296436 A (published Oct. 21, 2004)

PTL 3: JP 2014-125671 A (published Jul. 7, 2014)

PTL 4: JP 2005-302457 A (published Oct. 27, 2005)

PTL 5: JP 2015-103427 A (published Jun. 4, 2015)

### SUMMARY

### Technical Problems

However, as described in PTLs 1 to 5, even when the precision of openings of a vapor deposition mask is improved, problems other than the precision of openings of a vapor deposition mask may generate film thickness variation and film formation positional offset in the step of forming vapor deposition films.

When film thickness variation and film formation positional offset are generated in the step of forming vapor deposition films, such generation of film thickness variation and film formation positional offset leads to quality defects of an organic EL display device. As a result, it is necessary to detect the generation of film thickness variation and film formation positional offset in the above-described step.

Thus, to detect the generation of film thickness variation and film formation positional offset, it is necessary to regularly extract an active matrix substrate on which vapor deposition films are formed, and to inspect film thickness variation and film formation positional offset of vapor deposition films separately formed in a non-display region of the active matrix substrate.

To separately form the vapor deposition films for inspecting film thickness variation and film formation positional offset of vapor deposition films in the non-display region of the active matrix substrate, it is necessary to separately provide openings for forming vapor deposition films for inspection on the vapor deposition mask side. However, the openings for forming vapor deposition films for inspection are not provided in any of the vapor deposition masks described in PTLs 1 to 5.

Moreover, in a step of forming vapor deposition films in steps of producing a display device such as an organic EL display device, when multiple different vapor deposition films having the same pattern are formed on an active matrix substrate, multiple vapor deposition masks having the same opening pattern of vapor deposition masks are used.

Therefore, when the multiple different vapor deposition films having the same pattern are layered and formed on the active matrix substrate by using the multiple vapor deposition masks having the same opening pattern of vapor deposition masks, and without providing the openings for forming vapor deposition films for inspection, it is necessary to inspect film thickness variation and film formation positional offset by using the vapor deposition films layered and formed in a display region of the active matrix substrate, and there is a problem in the inspection of film thickness variation and film formation positional offset that is carried out at unsatisfactory precision.

The disclosure has been made in view of the above-described problem, and an object of the disclosure is to provide a display device producing method, a vapor deposition mask and an active matrix substrate that enable formation of vapor deposition films enabling highly precise inspection of film thickness variation and film formation positional offset.

### Solution to Problem

To solve the above-described problems, a method for producing a display device according to the disclosure includes: forming a layered film by using a vapor deposition mask including multiple openings that vapor deposition particles pass through and that are disposed in accordance with a fixed rule, and in the method, in the vapor deposition mask, a size of an opening group forming region in which the multiple openings are formed is larger than a size of a display region of an active matrix substrate, in a first step of forming a first vapor deposition film on the active matrix substrate, the first vapor deposition film is formed in the display region of the active matrix substrate via a first opening group including multiple first openings serving as part of the multiple openings of the vapor deposition mask, and the first vapor deposition film is formed outside the display region of the active matrix substrate via a second opening group including multiple second openings serving as remaining part of the multiple openings of the vapor deposition mask, and in a second step of forming a second vapor deposition film on the active matrix substrate, the vapor deposition mask is shifted in a direction of disposing at least part of the second opening group in the display region of the active matrix substrate, a layered film of the first vapor deposition film and the second vapor deposition film is formed in the display region of the active matrix substrate, and the second vapor deposition film is formed outside the display region of the active matrix substrate such that at least part of the second vapor deposition film does not overlap with the first vapor deposition film formed outside the display region of the active matrix substrate in the first step.

In accordance with the above-described method, since the second vapor deposition film can be formed outside the display region of the active matrix substrate such that at least part of the second vapor deposition film does not overlap with the first vapor deposition film formed outside the display region of the active matrix substrate in the first step, film thickness variation and film formation positional offset can be inspected at high precision by using the first vapor deposition film and the second vapor deposition film.

Note that the opening group forming region refers to a region located in the vapor deposition mask, and including multiple openings and being larger than the display region of the active matrix substrate.

To solve the above-described problems, a method for producing a display device according to the disclosure includes: forming a layered film by using a vapor deposition mask including one opening that vapor deposition particles pass through, and in the method, the one opening of the vapor deposition mask is larger than a display region of an active matrix substrate, in a third step of forming a third vapor deposition film on the active matrix substrate, the third vapor deposition film is formed in the display region of the active matrix substrate via a first portion of the one opening of the vapor deposition mask, and the third vapor deposition film is formed outside the display region of the active matrix substrate via a remaining second portion different from the first portion of the one opening of the vapor deposition mask, and in a fourth step of forming a fourth vapor deposition film on the active matrix substrate, the vapor deposition mask is shifted in one direction, a layered film including the third vapor deposition film and the fourth vapor deposition film is formed in the display region of the active matrix substrate, and the fourth vapor deposition film is formed outside the display region of the active matrix substrate such that the fourth vapor deposition film does not overlap with the third vapor deposition film formed outside the display region of the active matrix substrate in the third step.

In accordance with the above-described method, since the fourth vapor deposition film can be formed outside the display region of the active matrix substrate such that the fourth vapor deposition film does not overlap with the third vapor deposition film formed outside the display region of the active matrix substrate in the third step, film thickness variation and film formation positional offset can be inspected at high precision by using the third vapor deposition film and the fourth vapor deposition film.

To solve the above-described problems, a vapor deposition mask according to the disclosure includes multiple openings that vapor deposition particles pass through and that are disposed in accordance with a fixed rule, and in the vapor deposition mask, a size of an opening group forming region in which the multiple openings are formed is larger than a size of a display region of an active matrix substrate.

In accordance with the above-described configuration, since in the vapor deposition mask, the size of the region in which the multiple openings are formed is larger than the size of the display region of the active matrix substrate, unlayered vapor deposition films can be formed outside the display region of the active matrix substrate by shifting the vapor deposition mask in one direction to form multiple vapor deposition films. Therefore, the vapor deposition films enabling highly precise inspection of film thickness variation and film formation positional offset can be formed.

Note that the opening group forming region refers to a region located in the vapor deposition mask, and including the multiple openings and being larger than the display region of the active matrix substrate.

To solve the above-described problems, a vapor deposition mask according to the disclosure includes one opening that vapor deposition particles pass through, and in the vapor deposition mask, a size of one opening is larger than a size of a display region of an active matrix substrate.

In accordance with the above-described configuration, since in the vapor deposition mask, the size of the one opening is larger than the size of the display region of the active matrix substrate, unlayered vapor deposition films can be formed outside the display region of the active matrix substrate by shifting the vapor deposition mask in one direction to form multiple vapor deposition films. Therefore, the vapor deposition films enabling highly precise inspection of film thickness variation and film formation positional offset can be formed.

To solve the above-described problems, an active matrix substrate according to the disclosure includes a substrate, multiple active elements disposed on the substrate and multiple first electrodes disposed on the substrate and electrically connected to each of the multiple active elements, and in the active matrix substrate, a region in which the multiple first electrodes are formed includes a display region, a layered film including a hole transport layer and a light emitting layer is formed on each of the multiple first electrodes in the display region, and the hole transport layer and the light emitting layer are formed as a single layer outside the display region.

In accordance with the above-described configuration, since the hole transport layer and the light emitting layer are formed as a single layer outside the display region of the active matrix substrate, film thickness variation and film formation positional offset of the hole transport layer and the light emitting layer can be inspected at high precision.

### Advantageous Effects of Disclosure

In accordance with one aspect of the disclosure, it is possible to provide a display device producing method, a vapor deposition mask and an active matrix substrate that enable formation of vapor deposition films enabling highly precise inspection of film thickness variation and film formation positional offset.

### BRIEF DESCRIPTION OF DRAWINGS

FIG. 1 is a view illustrating a schematic configuration of an organic EL display device.

FIG. 2 is a view illustrating a schematic configuration of a vapor deposition mask.

FIG. 3 is a view illustrating a difference between a disposition position of the vapor deposition mask in a step of forming a hole transport layer and a disposition position of the vapor deposition mask in a step of forming a red light emitting layer.

FIG. 4 is a view illustrating a difference in a disposition position of the vapor deposition mask with respect to an active matrix substrate in the step of forming the hole transport layer and the step of forming the red light emitting layer.

FIG. 5 is a view explaining a step of inspecting film thickness variation and film formation positional offset of the hole transport layer and the red light emitting layer formed on the active matrix substrate.

FIGS. 6A and 6B are views illustrating a modification of the vapor deposition mask illustrated in FIG. 2.

FIG. 7 is a view illustrating a schematic configuration of a vapor deposition mask including third openings.

FIG. 8 is a view illustrating a difference between a disposition position of the vapor deposition mask in a step of forming a hole transport layer and a disposition position of the vapor deposition mask in a step of forming a red light emitting layer in the case of using the vapor deposition mask illustrated in FIG. 7.

FIG. 9 is a view illustrating the case where the hole transport layer and the red light emitting layer are formed on an active matrix substrate by using the vapor deposition mask illustrated in FIG. 7.

FIG. 10 is a view illustrating a vapor deposition mask including multiple divided masks.

FIG. 11 is a view illustrating a schematic configuration of another vapor deposition mask for forming a hole transport layer and a green light emitting layer.

FIG. 12 is a view illustrating a schematic configuration of still another vapor deposition mask for forming a hole transport layer and a blue light emitting layer.

FIG. 13 is a view illustrating the case where a hole transport layer, a green light emitting layer and a blue light emitting layer are further formed on the active matrix substrate illustrated in FIG. 9.

FIG. 14 is a view illustrating a schematic configuration of a vapor deposition mask used in a step of forming a hole injection layer and an electron transport layer.

FIG. 15 is a view illustrating an active matrix substrate on which a hole injection layer and an electron transport layer are formed by using the vapor deposition mask illustrated in FIG. 14.

### DESCRIPTION OF EMBODIMENTS

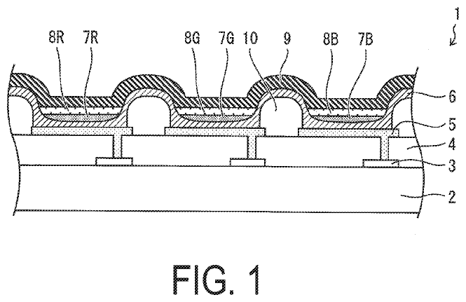

Embodiments of the disclosure will be described below with reference to FIGS. 1 to 15. Hereinafter, for convenience of description, a configuration having the same function as a configuration described in a specific embodiment is given the same reference sign, and the description of such a configuration may be omitted.

Note that in each of the following embodiments, an organic EL display device will be described as an example of a display device; however, the display device is not limited to the organic EL display device as long as the display device includes multiple vapor deposition films.

### Embodiment 1

Embodiment 1 of the disclosure will be described with reference to FIGS. 1 to 6.

FIG. 1 is a view illustrating a schematic configuration of an organic EL display device 1.

As illustrated, the organic EL display device 1 includes: a substrate 2; active elements 3 (for example, TFT elements) formed on one surface of the substrate 2; insulating films 4 covering the active elements 3; and edge covers 10 formed to cover first electrodes 5 (for example, ITO) electrically connected to the active elements 3 via contact holes formed in the insulating films 4, and to cover the insulating film 4 exposed at end portions of the first electrodes 5 and exposed between the two first electrodes 5 adjacent to each other.

The organic EL display device 1 further includes: a Hole Injection Layer (HIL layer) 6 formed almost entirely on a surface of a display region (not illustrated) in the substrate 2 to cover the first electrodes 5 and the edge covers 10; Hole Transport Layers (HTL layers) 7R, 7G and 7B serving as an upper layer of a region in which the first electrodes 5 are formed and being formed on the hole injection layer 6; a red light EMitting Layer (EML layer) 8R formed on the hole transport layer 7R; a green light EMitting Layer (EML layer) 8G formed on the hole transport layer 7G; a blue light EMitting Layer (EML layer) 8B formed on the hole transport layer 7B; an Electron Transport Layer (ETL layer) 9 formed almost entirely on a surface of a display region (not illustrated) in the substrate 2 to cover the hole injection layer 6, the red light emitting layer 8R, the green light emitting layer 8G and the blue light emitting layer 8B; and second electrodes (for example, a metal layer) formed almost entirely on a surface of a display region (not illustrated) in the substrate 2 to cover the electron transport layer 9.

The present embodiment will describe as an example the case where the hole transport layer 7R is formed and the red light emitting layer 8R is formed on the hole transport layer 7R by using a vapor deposition mask 11 in which multiple openings are formed in the same pattern; however, as described in other embodiments described below, the hole transport layer 7G may be formed and the green light emitting layer 8G may be formed on the hole transport layer 7G by using a vapor deposition mask in which multiple openings are formed in the same pattern, or the hole transport layer 7B may be formed and the blue light emitting layer 8B may be formed on the hole transport layer 7B by using a vapor deposition mask in which multiple openings are formed in the same pattern.

The vapor deposition mask 11 in which the multiple openings are formed in the same pattern includes a mask (also referred to as an Fine Metal Mask (FMM)) for forming separately patterning vapor deposition films.

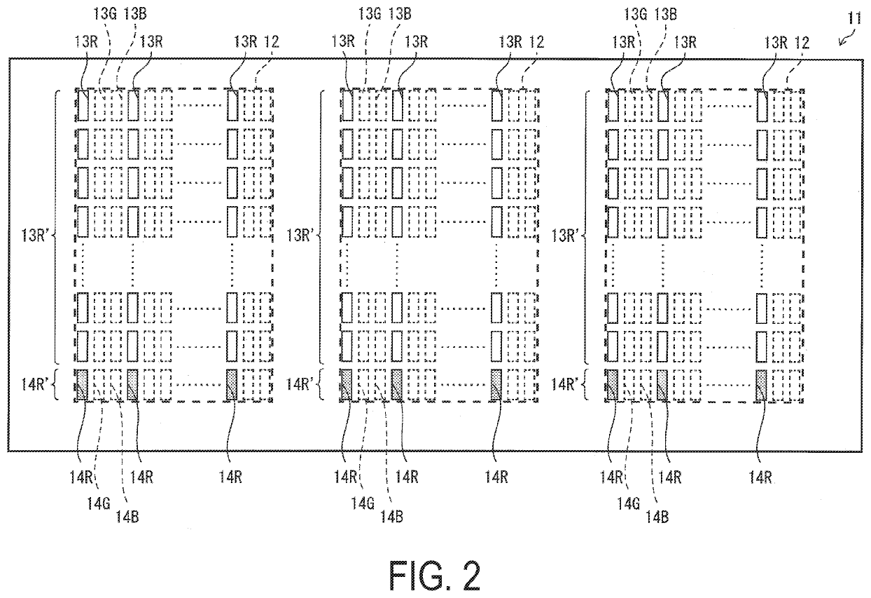

FIG. 2 is a view illustrating a schematic configuration of the vapor deposition mask 11.

As illustrated in FIG. 2, the vapor deposition mask 11 includes three opening group forming regions 12. A method in which multiple sub substrates (for example, 5 inches) are simultaneously created on a large mother substrate and cut to create individual sub substrates may be used to produce the organic EL display device 1 at a lower cost. The opening group forming regions 12 refer to mask regions corresponding to the sub substrates.

Each of the three opening group forming regions 12 includes multiple openings 13R and 14R that vapor deposition particles pass through. Each of the opening group forming regions 12 includes a first opening group 13R′ including the multiple first openings 13R repeatedly disposed in accordance with a fixed rule, and a second opening group 14R′ including multiple second openings 14R each having the same shape as a shape of each of the first openings 13R, and disposed adjacent to the first opening group 13R′ in accordance with the same rule as the fixed rule that the multiple first openings 13R are disposed in accordance with.

Note that the opening group forming regions 12 each include a region located in the vapor deposition mask 11, and the multiple openings 13R and 14R that vapor deposition particles pass through, and the opening group forming region being larger than a display region of an active matrix substrate 20.

In FIG. 2, multiple first openings 13G and 13B illustrated by dotted lines are virtual openings not really existing in the vapor deposition mask 11, and are illustrated for reference of an interval between the first openings 13R. In FIG. 2, multiple second openings 14G and 14B illustrated by dotted lines are virtual openings not really existing in the vapor deposition mask 11, and are illustrated for reference of an interval between the second openings 14R. Each of the three opening group forming regions 12 also includes the first openings 13G and 13B and the second openings 14G and 14B as virtual openings.

In the vapor deposition mask 11, a size of each of the opening group forming regions 12 serving as a region in which the multiple openings 13R and 14R are formed is larger than a size of a display region of an active matrix substrate (not illustrated).

The number of the openings 13R constituting the first opening group 13R′ is the number of pixels indicating a red gradation in the display region of the active matrix substrate, and the second openings 14R include openings for forming vapor deposition films outside the display region of the active matrix substrate.

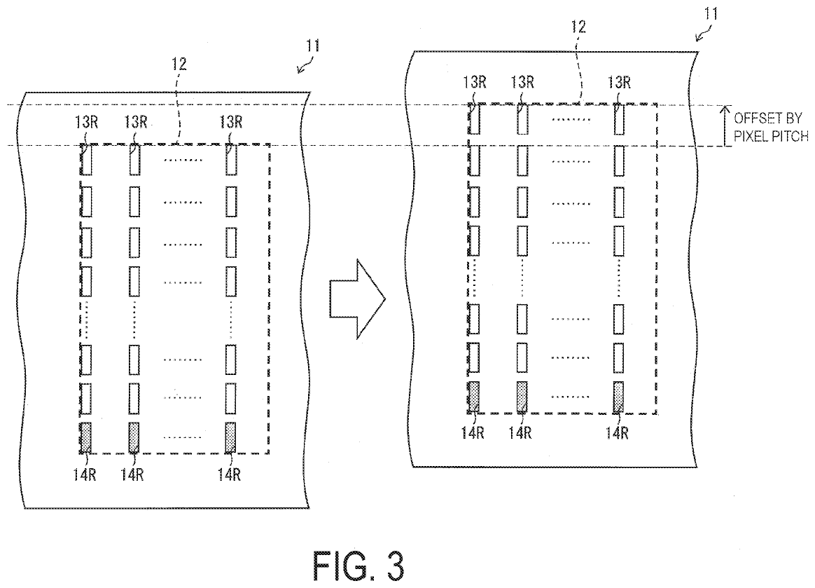

FIG. 3 is a view illustrating a difference between a disposition position of the vapor deposition mask 11 in a step of forming the hole transport layer 7R and a disposition position of the vapor deposition mask 11 in a step of forming the red light emitting layer 8R. Note that only one of the three opening group forming regions 12 of the vapor deposition mask 11 illustrated in FIG. 2 is illustrated in FIG. 3.

As illustrated in FIG. 3, the disposition position of the vapor deposition mask 11 in the step of forming the red light emitting layer 8R is offset by a pixel pitch, for example, by 30 μm toward the upper side in FIG. 3 of the disposition position of the vapor deposition mask 11 in the step of forming the hole transport layer 7R.

Note that in the present embodiment, as illustrated in FIG. 3, the width obtained by adding the width in a vertical direction in FIG. 3 in each of the first openings 13R or each of the second openings 14R with the width in the vertical direction in FIG. 3 between the first opening 13R and the second opening 14R adjacent to each other or the width in the vertical direction in FIG. 3 between the first openings 13R adjacent to each other is 30 μm, that is, since a pitch between the first openings 13R adjacent to each other in the direction of shifting the vapor deposition mask 11 (in the vertical direction in FIG. 3) is the same as a pitch between the first opening 13R and the second opening 14R adjacent to each other in the direction of shifting the vapor deposition mask 11, the vapor deposition mask 11 is offset by 30 μm; however, needless to say, the offset amount varies depending on a shape of each of the openings formed in the vapor deposition mask.

The hole transport layer 7R is formed on an active matrix substrate (not illustrated) at the disposition position of the vapor deposition mask 11 as in the left view of FIG. 3, and subsequently the red light emitting layer 8R is formed on an active matrix substrate (not illustrated) at the disposition position of the vapor deposition mask 11 as in the right view of FIG. 3.

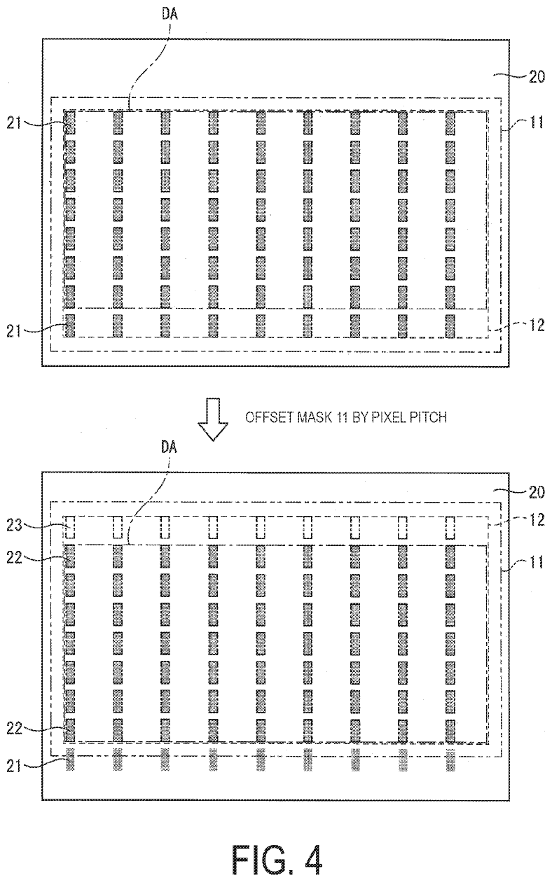

FIG. 4 is a view illustrating a difference in a disposition position of the vapor deposition mask 11 with respect to the active matrix substrate 20 in the step of forming the hole transport layer 7R and the step of forming the red light emitting layer 8R.

As illustrated in FIG. 4, in the vapor deposition mask 11, each of the opening group forming regions 12 in which the multiple openings are formed is larger than a display region DA of the active matrix substrate 20.

The vapor deposition mask 11 is set and aligned (positioned) with respect to the active matrix substrate 20 such that in the step of forming the hole transport layer 7R, each of the first openings 13R (not illustrated) in the vapor deposition mask 11 overlaps in a plan view with each of the first electrodes (not illustrated) in the display region DA of the active matrix substrate 20, and such that each of the second openings 14R (not illustrated) in the vapor deposition mask 11 is disposed outside the display region DA of the active matrix substrate 20.

Thus, the hole transport layer 7R is formed in a state where the vapor deposition mask 11 is set and aligned with respect to the active matrix substrate 20. As a result, island shaped vapor deposition films 21 serving as the hole transport layer 7R can be formed in the display region DA of the active matrix substrate 20 and outside the display region DA of the active matrix substrate 20.

Subsequently, the vapor deposition mask 11 is set and aligned (positioned) with respect to the active matrix substrate 20 such that in the step of forming the red light emitting layer 8R, as illustrated in FIG. 3, the vapor deposition mask 11 is offset by a pixel pitch toward the upper side, and part of the first openings 13R in the vapor deposition mask 11 (not illustrated) (first openings other than first openings in the uppermost line) and each of the second openings 14R (not illustrated) overlap in a plan view with each of the first electrodes (not illustrated) in the display region DA of the active matrix substrate 20, and such that the first openings in the uppermost line in the first openings 13R (not illustrated) in the vapor deposition mask 11 do not overlap, in a plan view outside the display region DA of the active matrix substrate 20, with the island shaped vapor deposition films 21 formed outside the display region DA of active matrix substrate 20 in the step of forming the hole transport layer 7R.

Thus, the red light emitting layer 8R is formed in a state where the vapor deposition mask 11 is set and aligned with respect to the active matrix substrate 20. As a result, a layered film 22 of the hole transport layer 7R and the red light emitting layer 8R can be formed in the display region DA of the active matrix substrate 20, and the island shaped vapor deposition films 21 serving as the hole transport layer 7R and island shaped vapor deposition films 23 serving as the red light emitting layer 8R can be formed as a single film outside the display region DA of the active matrix substrate 20.

The present embodiment describes as an example the case where the island shaped vapor deposition films 21 serving as the hole transport layer 7R are formed as a single film on the lower side outside the display region DA of the active matrix substrate 20, and the island shaped vapor deposition films 23 serving as the red light emitting layer 8R are formed as a single film on the upper side outside the display region DA of the active matrix substrate 20. However, the present embodiment is not limited to this case. The island shaped vapor deposition films 21 serving as the hole transport layer 7R may be formed as a single film on the upper side outside the display region DA of the active matrix substrate 20, and the island shaped vapor deposition films 23 serving as the red light emitting layer 8R may be formed as a single film on the lower side outside the display region DA of the active matrix substrate 20, by changing the disposition position of the vapor deposition mask 11 with respect to the active matrix substrate 20 in the step of forming the hole transport layer 7R, and changing the direction of offsetting the vapor deposition mask 11 in the step of forming the red light emitting layer 8R.

Moreover, the present embodiment describes as an example the case where the second opening group 14R′ is disposed on the lower side of the first opening group 13R. However, the present embodiment is not limited to this case. The second opening group 14R′ may be disposed on the upper side of the first opening group 13R′, and the second opening group 14R′ may further be disposed on each of the right side and the left side of the first opening group 13R′. Note that when the second opening group 14R′ is disposed on each of the right side and the left side of the first opening group 13R′, the vapor deposition films 21 and the vapor deposition films 23 are formed as a single film on the right side and the left side outside the display region DA of the active matrix substrate 20.

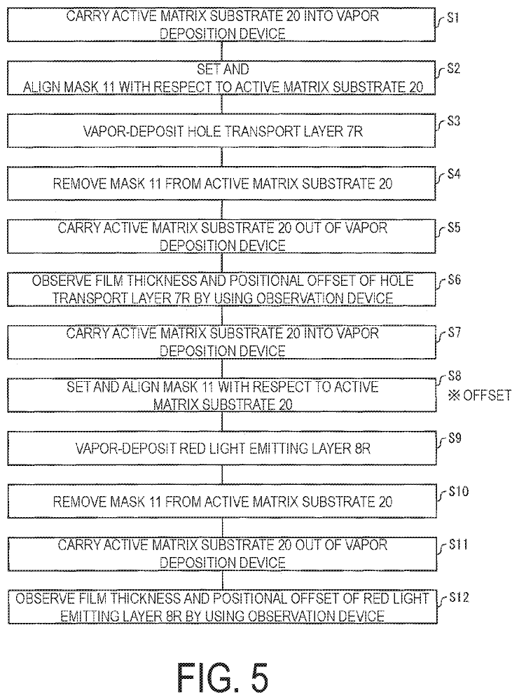

FIG. 5 is a view explaining a step of inspecting film thickness variation and film formation positional offset of the hole transport layer 7R and the red light emitting layer 8R formed on the active matrix substrate 20.

First, the active matrix substrate 20 is carried into a vapor deposition device (S1) and, as illustrated in FIGS. 3 and 4, the vapor deposition mask 11 is set and aligned (positioned) with respect to the active matrix substrate 20 (S2) such that each of the first openings 13R (not illustrated) in the vapor deposition mask 11 overlaps in a plan view with each of the first electrodes (not illustrated) in the display region DA of the active matrix substrate 20, and such that each of the second openings 14R (not illustrated) in the vapor deposition mask 11 is disposed outside the display region DA of the active matrix substrate 20.

Then, the hole transport layer 7R is formed (S3) in a state where the vapor deposition mask 11 is thus set and aligned with respect to the active matrix substrate 20.

Then, the vapor deposition mask 11 is removed from the active matrix substrate 20 (S4), and the active matrix substrate 20 is carried out of the vapor deposition device (S5).

Subsequently, the film thickness and positional offset of each of the island shaped vapor deposition films 21 serving as the hole transport layer 7R as a single layer and formed outside the display region DA of the active matrix substrate 20 are observed by using an observation device (S6).

After the observation, the active matrix substrate 20 is carried into the vapor deposition device again (S7) and, as illustrated in FIGS. 3 and 4, the vapor deposition mask 11 is set and aligned (positioned) with respect to the active matrix substrate 20 (S8) such that the vapor deposition mask 11 is offset by a pixel pitch toward the upper side, and part of the first opening 13R in the vapor deposition mask 11 (not illustrated) (first openings other than first openings in the uppermost line) and each of the second openings 14R (not illustrated) overlap in a plan view with each of the first electrodes (not illustrated) in the display region DA of the active matrix substrate 20, and such that the first openings in the uppermost line in the first openings 13R (not illustrated) in the vapor deposition mask 11 do not overlap, in a plan view outside the display region DA of the active matrix substrate 20, with the island shaped vapor deposition films 21 formed outside the display region DA of the active matrix substrate 20 in the step of forming the hole transport layer 7R.

Then, the red light emitting layer 8R is formed (S9) in a state where the vapor deposition mask 11 is thus set and aligned with respect to the active matrix substrate 20.

Then, the vapor deposition mask 11 is removed from the active matrix substrate 20 (S10), and the active matrix substrate 20 is carried out of the vapor deposition device (S11).

Subsequently, the film thickness and positional offset of each of the island shaped vapor deposition films 23 serving as the red light emitting layer 8R as a single layer and formed outside the display region DA of the active matrix substrate 20 are observed by using the observation device (S12).

Thus, it is possible to realize the method for producing the organic EL display device 1 that enables formation of vapor deposition films enabling highly precise inspection of film thickness variation and film formation positional offset.

The present embodiment describes as an example the case where as illustrated in FIG. 5, the film thickness and positional offset of each of the island shaped vapor deposition films 21 serving as the hole transport layer 7R as a single layer and formed outside the display region DA of the active matrix substrate 20 are observed, and subsequently the red light emitting layer 8R is formed on the active matrix substrate 20, and again the film thickness and positional offset of each of the island shaped vapor deposition films 23 serving as the red light emitting layer 8R as a single layer and formed outside the display region DA of the active matrix substrate 20 are observed. However, the present embodiment is not limited to this case. The hole transport layer 7R and the red light emitting layer 8R may be formed first on the active matrix substrate 20, and subsequently the film thickness and positional offset of each of the island shaped vapor deposition films 21 serving as the hole transport layer 7R as a single layer and formed outside the display region DA of the active matrix substrate 20 may be observed, and the film thickness and positional offset of each of the island shaped vapor deposition films 23 serving as the red light emitting layer 8R as a single layer and formed outside the display region DA of the active matrix substrate 20 may be observed.

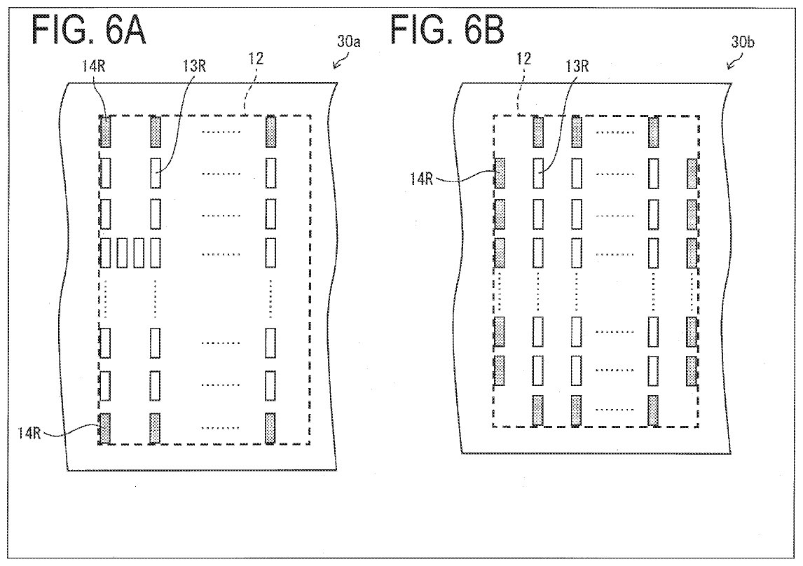

FIGS. 6A and 6B are views illustrating a modification of the vapor deposition mask 11 illustrated in FIG. 2. FIG. 6A is a view illustrating a schematic configuration of a vapor deposition mask 30a including multiple second openings 14R on the upper sides and the lower sides of the multiple first openings 13R, and FIG. 6B is a view illustrating a schematic configuration of a vapor deposition mask 30b including multiple second openings 14R provided on the upper sides, the right sides, the lower sides and the left sides of the multiple first openings 13R.

In the case of the vapor deposition mask 30a illustrated in FIG. 6A, since a direction of shifting the vapor deposition mask 30a can be any of an upward direction, a downward direction, a right direction and a left direction, a degree of freedom in a direction in which the vapor deposition mask 30a is offset increases.

Moreover, in the case of the vapor deposition mask 30b illustrated in FIG. 6B, since a direction of shifting the vapor deposition mask 30b can be any of an upward direction, a downward direction, a right direction and a left direction, a degree of freedom in a direction in which the vapor deposition mask 30b is offset increases.

Note that in the case of the vapor deposition masks 30a and 30b illustrated in FIGS. 6A and FIG. 6B, the island shaped vapor deposition films 21 serving as the hole transport layer 7R as a single layer, the island shaped vapor deposition films 23 serving as the red light emitting layer 8R as a single layer, and the island shaped layered film 22 of the hole transport layer 7R and the red light emitting layer 8R are formed outside the display region DA of the active matrix substrate 20, and the film thickness and positional offset of each of the island shaped vapor deposition films 21 serving as the hole transport layer 7R as a single layer and each of the island shaped vapor deposition films 23 serving as the red light emitting layer 8R as a single layer are observed, and as a result, film thickness variation and film formation positional offset of the vapor deposition films can be inspected at high precision.

Note that the present embodiment describes as an example the case where the vapor deposition mask 11 is fixed to the active matrix substrate 20 to carry out vapor deposition; however, the present embodiment is not limited to this case, and while the vapor deposition mask 11 is moved step by step to the active matrix substrate 20, vapor deposition (also referred to as a step vapor deposition) may be carried out for each of the predetermined regions of the active matrix substrate 20, or while the active matrix substrate 20 is moved step by step to the vapor deposition mask 11, vapor deposition (also referred to as a step vapor deposition) may be carried out for each of the predetermined regions of the active matrix substrate 20.

Moreover, the vapor deposition mask 11 may be fixed to the active matrix substrate 20, and then a vapor deposition material may be heated and caused to evaporate (when the vapor deposition material is a liquid material) or sublimate (when the vapor deposition material is a solid material) to generate gaseous vapor deposition particles, and a line source (not illustrated) serving as a vapor deposition source for emission from multiple slit nozzles to the outside may be moved in one direction to carry out vapor deposition. In such a case, multiple second openings 14R are preferably provided in the direction of moving the line source (not illustrated) in one direction. This is because the vapor deposition mask 11 may be shifted along one direction of moving the line source (not illustrated).

Thus, since the hole transport layer 7R and the red light emitting layer 8R can be formed by using the vapor deposition mask 11 having the same opening pattern, and film thickness variation and film formation positional offset of the hole transport layer 7R and the red light emitting layer 8R can be inspected at high precision, the method for producing the organic EL display device 1, the vapor deposition mask 11 and the active matrix substrate 20 that enable formation of vapor deposition films enabling highly precise inspection of film thickness variation and film formation positional offset can be realized without increasing a production cost of a mask.

Moreover, since film thickness variation and film formation positional offset of the hole transport layer 7R and the red light emitting layer 8R can be inspected at high precision by using the active matrix substrate 20 used for production as is, a substrate for inspection need not be separately produced, and since the active matrix substrate 20 can be returned to a production line after inspection, there is no deterioration in a yield.

### Embodiment 2

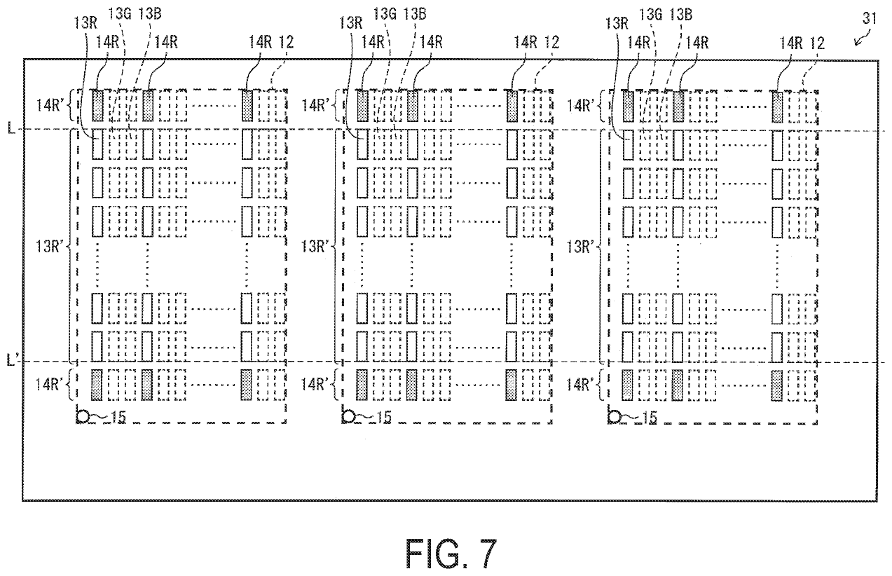

Next, Embodiment 2 of the disclosure will be described with reference to FIGS. 7 to 10. The present embodiment is different from Embodiment 1 in the use of a vapor deposition mask 31 including multiple second openings 14R on the upper side and the lower side of each of multiple first openings 13R, and further including third openings 15. Other points in the present embodiment are as described in Embodiment 1. For convenience of description, members having the same functions as the members in Embodiment 1 illustrated in the figures are given the same reference signs, and description of these members will be omitted.

FIG. 7 is a view illustrating a schematic configuration of the vapor deposition mask 31 including the third openings 15.

As illustrated in FIG. 7, each of three opening group forming regions 12 includes the multiple openings 13R, 14R and 15 that vapor deposition particles pass through. That is, each of the opening group forming regions 12 includes: a first opening group 13R′ including the multiple first openings 13R repeatedly disposed in accordance with a fixed rule; two second opening groups 14R′ including multiple second openings 14R each having the same shape as a shape of each of the first openings 13R, and disposed adjacent to opposing two sides (dotted lines L and L′ in FIG. 7) in a boundary of the first opening group 13R′ in accordance with the same rule as the fixed rule that the multiple first openings 13R are disposed in accordance with; and the third openings 15.

In FIG. 7, the multiple first openings 13G and 13B illustrated by dotted lines are virtual openings not really existing in the vapor deposition mask 11, and are illustrated for reference of an interval between the first openings 13R and an interval between the second openings 14R.

Note that the opening group forming region 12 includes a region located in the vapor deposition mask 31, and including the multiple openings 13R, 14R and 15 that vapor deposition particles pass through and being larger than a display region DA of an active matrix substrate 20.

In FIG. 7, the multiple first openings 13G and 13B illustrated by dotted lines are virtual openings not really existing in the vapor deposition mask 31 and are illustrated for reference of an interval between the first openings 13R, and the multiple second openings 14G and 14B illustrated by dotted lines are virtual openings not really existing in the vapor deposition mask 31 and are illustrated for reference of an interval between the second openings 14R. Each of the three opening group forming regions 12 also includes the first openings 13G and 13B and the second openings 14G and 14B as virtual openings.

The number of the openings 13R constituting the first opening group 13R′ is the number of pixels indicating a red gradation in the display region DA of the active matrix substrate 20, the second openings 14R are openings for forming vapor deposition films outside the display region DA of the active matrix substrate 20, and the third openings 15 are openings for forming a vapor deposition film for inspection in a region outside the display region DA of the active matrix substrate 20 and away from the display region DA of the active matrix substrate 20.

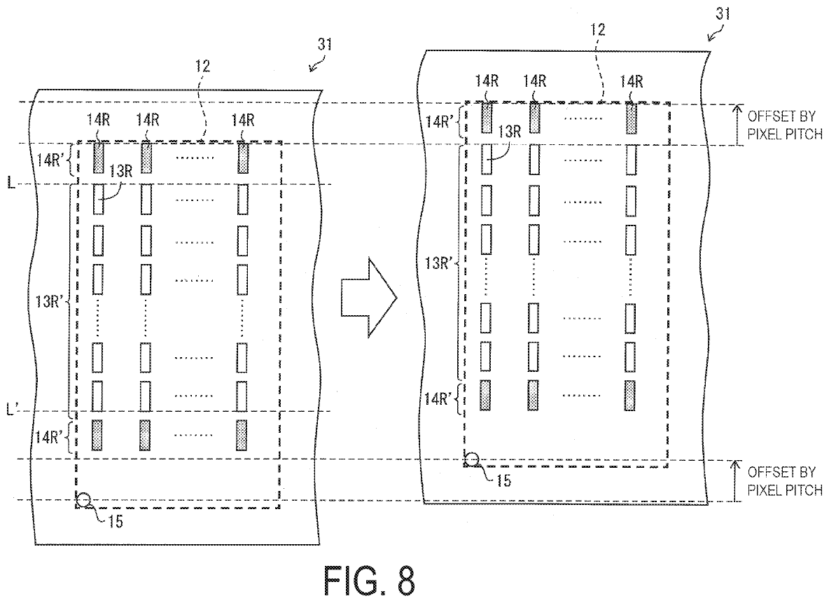

FIG. 8 is a view illustrating a difference between a disposition position of the vapor deposition mask 31 in forming a hole transport layer 7R and a disposition position of the vapor deposition mask 31 in forming a red light emitting layer 8R. Note that only one of the three opening group forming regions 12 of the vapor deposition mask 31 illustrated in FIG. 7 is illustrated in FIG. 8.

As illustrated in FIG. 8, the disposition position of the vapor deposition mask 31 in forming the red light emitting layer 8R is offset by a pixel pitch, for example, by 30 μm toward the upper side in FIG. 8 of the disposition position of the vapor deposition mask 31 in forming the hole transport layer 7R.

The hole transport layer 7R is formed on an active matrix substrate (not illustrated) at the disposition position of the vapor deposition mask 31 as in the left view of FIG. 8, and subsequently the red light emitting layer 8R is formed on an active matrix substrate (not illustrated) at the disposition position of the vapor deposition mask 31 as in the right view of FIG. 8.

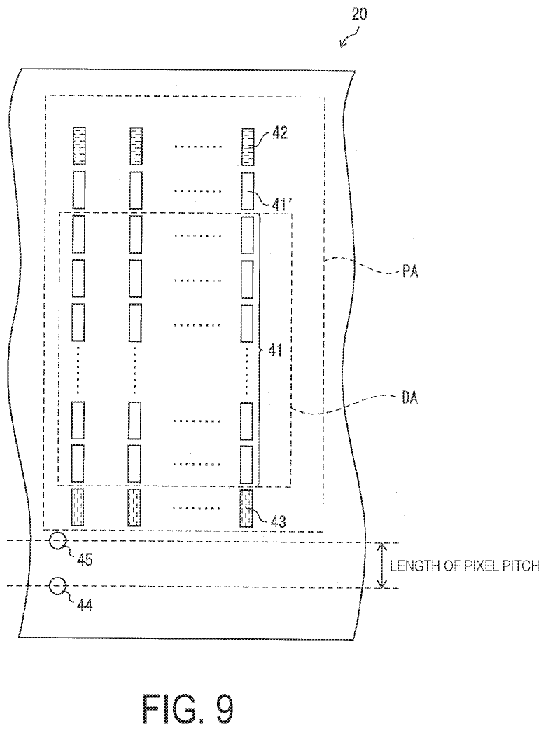

FIG. 9 is a view illustrating the case where the hole transport layer 7R and the red light emitting layer 8R are formed on the active matrix substrate 20 by using the vapor deposition mask 31 illustrated in FIG. 7.

As illustrated in FIG. 9, an island shaped layered film 41 including the hole transport layer 7R and the red light emitting layer 8R layered one on another is formed in the display region DA of the active matrix substrate 20, and a layered film 41′ including the hole transport layer 7R and the red light emitting layer 8R layered one on another, vapor deposition films 42 each including the red light emitting layer 8R as a single layer, vapor deposition films 43 each including the hole transport layer 7R as a single layer, a vapor deposition film for inspection 44 including the hole transport layer 7R as a single layer, and a vapor deposition film for inspection 45 including the red light emitting layer 8R as a single layer are formed outside the display region DA of the active matrix substrate 20.

Then, as illustrated in FIG. 9, the vapor deposition film for inspection 44 including the hole transport layer 7R as a single layer, and the vapor deposition film for inspection 45 including the red light emitting layer 8R as a single layer are formed outside a protection film forming region PA located outside the display region DA of the active matrix substrate 20.

Therefore, before the protection film is formed, film thickness variation and film formation positional offset of the hole transport layer 7R and the red light emitting layer 8R can be inspected at high precision by using the vapor deposition films 42 each including the red light emitting layer 8R as a single layer and formed outside the display region DA of the active matrix substrate 20, and the vapor deposition films 43 each including the hole transport layer 7R as a single layer and formed outside the display region DA of the active matrix substrate 20.

Then, after the protection film is formed, film thickness variation and film formation positional offset of the hole transport layer 7R and the red light emitting layer 8R can be inspected at high precision by using the vapor deposition film for inspection 44 including the hole transport layer 7R as a single layer and formed outside the protection film forming region PA located outside the display region DA of the active matrix substrate 20, and the vapor deposition film for inspection 45 including the red light emitting layer 8R as a single layer and formed outside the protection film forming region PA.

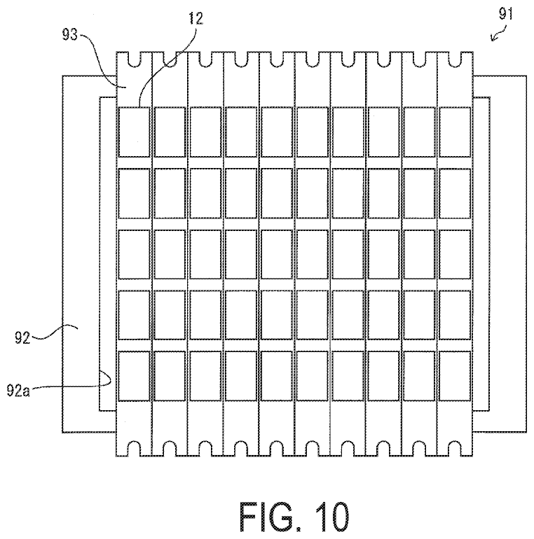

FIG. 10 is a view illustrating a vapor deposition mask 91 including multiple divided masks 93.

As illustrated in FIG. 10, each of the divided masks 93 includes the five opening group forming regions 12 illustrated in FIG. 7.

The vapor deposition mask 91 is disposed such that the multiple divided masks 93 are fixed (stretched) with tension to a frame 92 including a large opening 92a in a central part, and the opening group forming regions 12 in each of multiple divided masks 93 overlap with the large opening 92a in the frame 92 in a plan view.

Each of the multiple divided masks 93 includes a metal plate such as an invar material, and one surface of the divided mask 93 is a surface opposing the active matrix substrate 20.

In the case of the vapor deposition mask 91 including the multiple divided masks 93 illustrated in FIG. 10, as with the case illustrated in FIG. 8, a disposition position of the vapor deposition mask 91 in forming the red light emitting layer 8R is offset by a pixel pitch toward the upper side in FIG. 10 of a disposition position of the vapor deposition mask 91 in forming the hole transport layer 7R. As a result, the vapor deposition films 42 each including the red light emitting layer 8R as a single layer, and the vapor deposition films 43 each including the hole transport layer 7R as a single layer can be formed outside the display region DA of the active matrix substrate 20. Accordingly, before the protection film is formed, film thickness variation and film formation positional offset of the hole transport layer 7R and the red light emitting layer 8R can be inspected at high precision by using the vapor deposition films 42 and the vapor deposition films 43.

Then, the vapor deposition film for inspection 44 including the hole transport layer 7R as a single layer, and the vapor deposition film for inspection 45 including the red light emitting layer 8R as a single layer can be formed outside the protection film forming region PA located outside the display region DA of the active matrix substrate 20. Accordingly, after the protection film is formed, film thickness variation and film formation positional offset of the hole transport layer 7R and the red light emitting layer 8R can be inspected at high precision by using the vapor deposition film for inspection 44 and the vapor deposition film for inspection 45.

Note that the present embodiment describes as an example the vapor deposition mask 91 including the multiple divided masks 93 including the third openings 15; however, the present embodiment is not limited to this example, and the multiple divided masks 93 may not include the third openings 15 as in Embodiment 1.

The present embodiment describes as an example the case where a shape of each of the third openings 15 is circular. However, the present embodiment is not limited to this case. The shape of each of the third openings 15 is preferably the same as a shape of each of the first openings 13R and a shape of each of the second openings 14R to inspect film thickness variation and film formation positional offset at higher precision.

### Embodiment 3

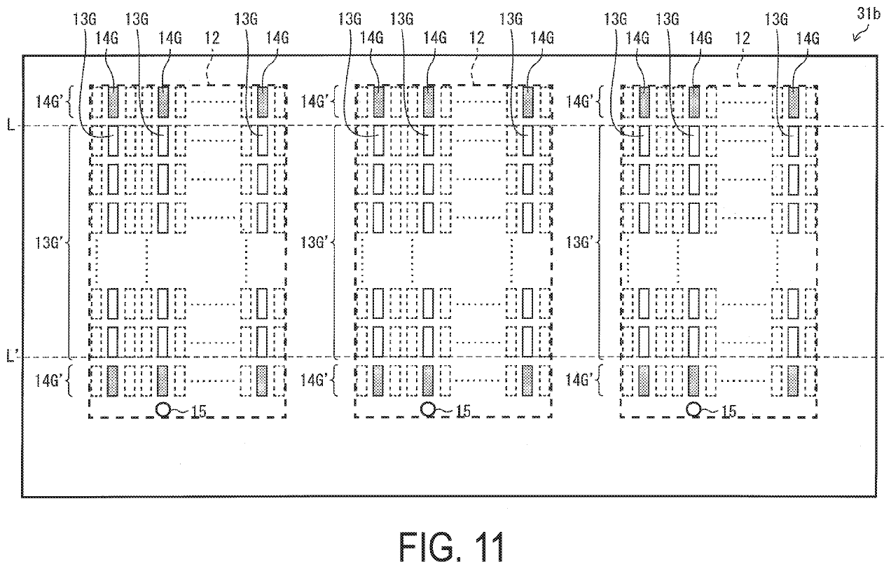

Next, Embodiment 3 of the disclosure will be described with reference to FIGS. 11 to 13. The present embodiment is different from Embodiments 1 and 2 in that a hole transport layer 7G and a green light emitting layer 8G are formed by using a vapor deposition mask 31b including multiple openings formed in the same pattern, and a hole transport layer 7B and a blue light emitting layer 8B are formed by using a vapor deposition mask 31c including multiple openings formed in the same pattern. Other points in the present embodiment are as described in Embodiments 1 and 2. For convenience of description, members having the same functions as the members in Embodiments 1 and 2 illustrated in the drawings are given the same reference signs, and description of these members will be omitted.

FIG. 11 is a view illustrating a schematic configuration of the vapor deposition mask 31b.

As illustrated in FIG. 11, positions of first openings 13G, second openings 14G and third openings 15 in the vapor deposition mask 31b are different from the positions of the first openings 13R, the second openings 14R and the third openings 15 in the vapor deposition mask 31 illustrated in FIG. 7.

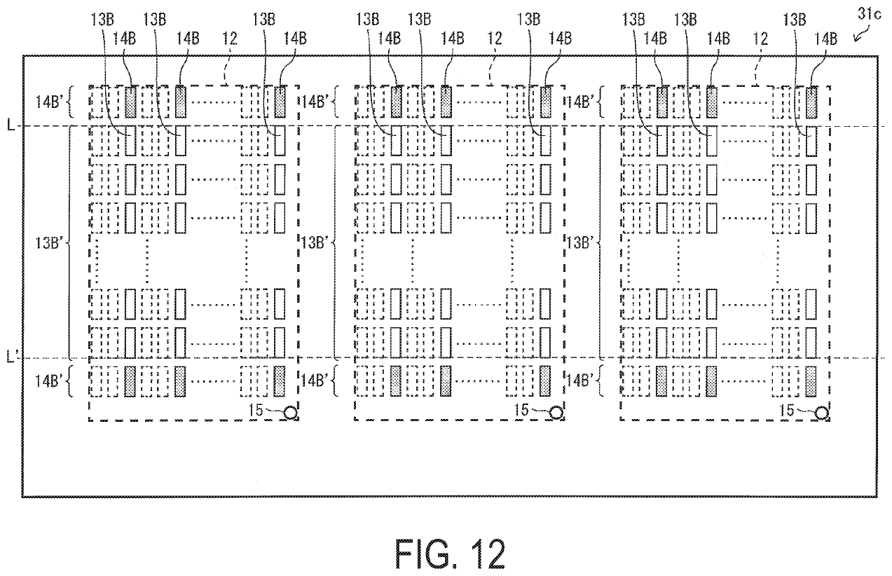

FIG. 12 is a view illustrating a schematic configuration of the vapor deposition mask 31c.

As illustrated in FIG. 12, positions of first openings 13B, second openings 14B and third openings 15 in the vapor deposition mask 31c are different from the positions of the first openings 13R, the second openings 14R and the third openings 15 in the vapor deposition mask 31 illustrated in FIG. 7, and are different from the first openings 13G, the second openings 14G and the third openings 15 in the vapor deposition mask 31b illustrated in FIG. 11.

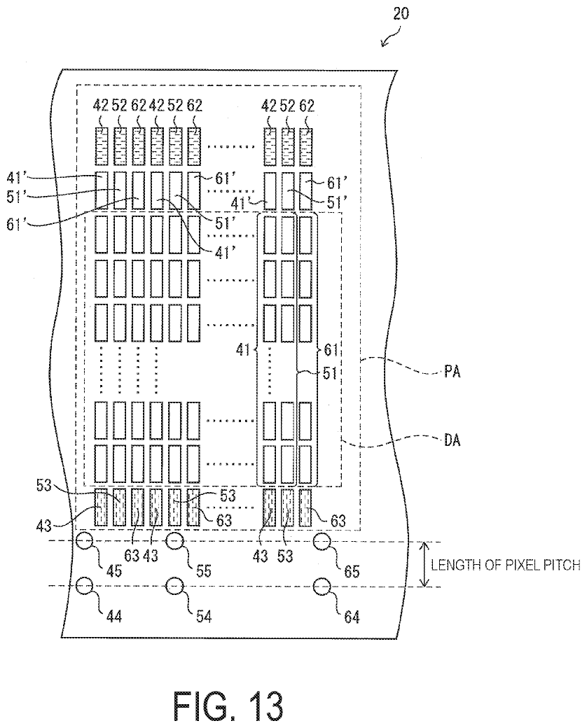

FIG. 13 is a view illustrating the case where the hole transport layer 7G, the green light emitting layer 8G, the hole transport layer 7B and the blue light emitting layer 8B are formed by using the vapor deposition mask 31b and the vapor deposition mask 31c on the active matrix substrate 20 illustrated in FIG. 9 on which a hole transport layer 7R and a red light emitting layer 8R are formed.

As illustrated in FIG. 13, an island shaped layered film 41 including the hole transport layer 7R and the red light emitting layer 8R layered one on another, an island shaped layered film 51 including the hole transport layer 7G and the green light emitting layer 8G layered one on another, and an island shaped layered film 61 including the hole transport layer 7B and the blue light emitting layer 8B layered one on another are formed in a display region DA of the active matrix substrate 20, and a layered film 41′ including the hole transport layer 7R and the red light emitting layer 8R layered one on another, a layered film 51′ including the hole transport layer 7G and the green light emitting layer 8G layered one on another, a layered film 61′ including the hole transport layer 7B and the blue light emitting layer 8B layered one on another, vapor deposition films 42 each including the red light emitting layer 8R as a single layer, vapor deposition films 43 each including the hole transport layer 7R as a single layer, vapor deposition films 52 each including the green light emitting layer 8G as a single layer, vapor deposition films 53 each including the hole transport layer 7G as a single layer, vapor deposition films 62 each including the blue light emitting layer 8B as a single layer, vapor deposition films 63 each including the hole transport layer 7B as a single layer, a vapor deposition film for inspection 44 including the hole transport layer 7R as a single layer, a vapor deposition film for inspection 45 including the red light emitting layer 8R as a single layer, a vapor deposition film for inspection 54 including the hole transport layer 7G as a single layer, a vapor deposition film for inspection 55 including the green light emitting layer 8G as a single layer, a vapor deposition film for inspection 64 including the hole transport layer 7B as a single layer, and a vapor deposition film for inspection 65 including the blue light emitting layer 8B as a single layer are formed outside the display region DA of the active matrix substrate 20.

Then, as illustrated in FIG. 13, the vapor deposition films for inspection 44, 45, 54, 55, 64 and 65 are formed outside a protection film forming region PA located outside the display region DA of the active matrix substrate 20.

Therefore, before the protection film is formed, film thickness variation and film formation positional offset of the hole transport layer 7R, the red light emitting layer 8R, the hole transport layer 7G, the green light emitting layer 8G, the hole transport layer 7B and the blue light emitting layer 8B can be inspected at high precision by using the vapor deposition films 42, 43, 52, 53, 62 and 63 each formed as a single layer and formed outside the display region DA of the active matrix substrate 20.

Then, after the protection film is formed, film thickness variation and film formation positional offset of the hole transport layer 7R, the red light emitting layer 8R, the hole transport layer 7G, the green light emitting layer 8G, the hole transport layer 7B and the blue light emitting layer 8B can be inspected at high precision by using the vapor deposition films for inspection 44, 45, 54, 55, 64 and 65 each formed as a single layer and formed outside the protection film forming region PA located outside the display region DA of the active matrix substrate 20.

### Embodiment 4

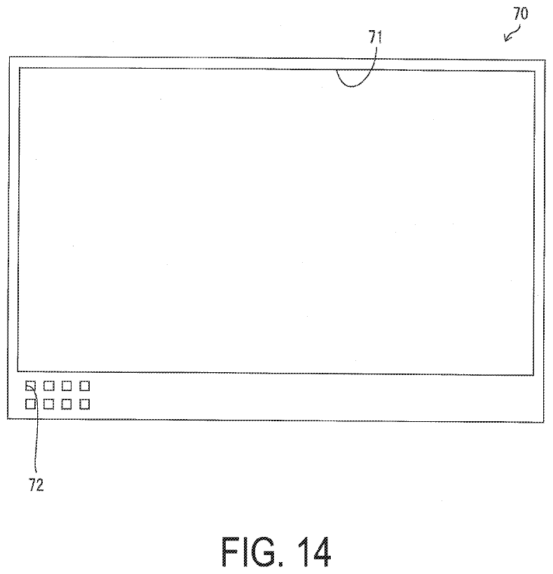

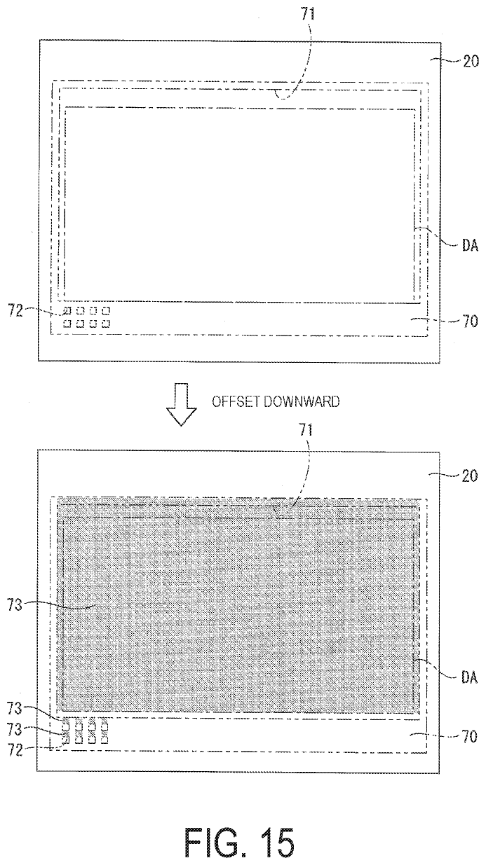

Next, Embodiment 4 of the disclosure will be described with reference to FIGS. 14 and 15. The present embodiment is different from Embodiments 1 to 3 in that a hole injection layer 6 and an electron transport layer 9 are formed almost entirely on a surface of a display region in an active matrix substrate by using a vapor deposition mask 70 including one opening 71 that vapor deposition particles pass through. Other points in the present embodiment are as described in Embodiments 1 to 3. For convenience of description, members having the same functions as the members in Embodiments 1 to 3 illustrated in the drawings are given the same reference signs, and description of these members will be omitted.

FIG. 14 is a view illustrating a schematic configuration of the vapor deposition mask 70.

The vapor deposition mask 70 including the one opening 71 that vapor deposition particles pass through includes a mask for common vapor deposition film formation (also referred to as a CMM (Common Metal Mask)).

As illustrated in FIG. 14, the vapor deposition mask 70 includes the one opening 71 that vapor deposition particles pass through, and third openings 72 serving as openings for forming a vapor deposition film for inspection in a region away from the display region of the active matrix substrate.

FIG. 15 is a view illustrating a difference in a disposition position of the vapor deposition mask 70 with respect to an active matrix substrate 20 in a step of forming the hole injection layer 6 and a step of forming the electron transport layer 9.

As illustrated in FIG. 15, a size of the opening 71 in the vapor deposition mask 70 is larger than a size of a display region DA of the active matrix substrate 20.

In the step of forming the hole injection layer 6, the opening 71 of the vapor deposition mask 70 is shifted toward the upper side of the display region DA of the active matrix substrate 20, and vapor deposition films 73 each including the hole injection layer 6 as a single layer are formed on the upper side of the display region DA of the active matrix substrate 20 together with the display region DA of the active matrix substrate 20. Then, the vapor deposition films 73 each including the hole injection layer 6 as a single layer are formed as vapor deposition films for inspection in a region away from the display region DA of the active matrix substrate 20 via the third openings 72 on the lower side of the display region DA of the active matrix substrate 20.

Then, in the step of forming the electron transport layer 9, the vapor deposition mask 70 is offset downward, a layered film including the hole injection layer 6 and the electron transport layer 9 is formed in the display region DA of the active matrix substrate 20, and vapor deposition films (not illustrated) each including the electron transport layer 9 as a single layer are formed on the lower side of the display region DA of the active matrix substrate 20. Then, vapor deposition films (not illustrated) each including the electron transport layer 9 as a single layer are formed as vapor deposition films for inspection in a region away from the display region DA of the active matrix substrate 20 via the third openings 72 on the lower side of the display region DA of the active matrix substrate 20.

Thus, the vapor deposition films 73 each including the hole injection layer 6 as a single layer and not covered with the electron transport layer 9 are formed on the upper side of the display region DA of the active matrix substrate 20, and the vapor deposition films each including the electron transport layer 9 as a single layer and not overlapping the hole injection layer 6 are formed on the lower side of the display region DA of the active matrix substrate 20. Therefore, before a protection film is formed, film thickness variation and film formation positional offset of the hole injection layer 6 and the electron transport layer 9 can be inspected at high precision by using these single films.

Then, after the protection film is formed, film thickness variation and film formation positional offset of the hole injection layer 6 and the electron transport layer 9 can be inspected at high precision by using the single layers formed as the vapor deposition films for inspection in the region away from the display region DA of the active matrix substrate 20.

### Supplement

A method for producing a display device according to aspect 1 of the disclosure includes: forming a layered film by using a vapor deposition mask including multiple openings that vapor deposition particles pass through and that are disposed in accordance with a fixed rule, and in the method, in the vapor deposition mask, a size of an opening group forming region in which the multiple openings are formed is larger than a size of a display region of an active matrix substrate, in a first step of forming a first vapor deposition film on the active matrix substrate, the first vapor deposition film is formed in the display region of the active matrix substrate via a first opening group including multiple first openings serving as part of the multiple openings of the vapor deposition mask, and the first vapor deposition film is formed outside the display region of the active matrix substrate via a second opening group including multiple second openings serving as remaining part of the multiple openings of the vapor deposition mask, and in a second step of forming a second vapor deposition film on the active matrix substrate, the vapor deposition mask is shifted in a direction of disposing at least part of the second opening group in the display region of the active matrix substrate, a layered film of the first vapor deposition film and the second vapor deposition film is formed in the display region of the active matrix substrate, and the second vapor deposition film is formed outside the display region of the active matrix substrate such that at least part of the second vapor deposition film does not overlap with the first vapor deposition film formed outside the display region of the active matrix substrate in the first step.

In accordance with the above-described method, since the second vapor deposition film can be formed outside the display region of the active matrix substrate such that at least part of the second vapor deposition film does not overlap with the first vapor deposition film formed outside the display region of the active matrix substrate in the first step, film thickness variation and film formation positional offset can be inspected at high precision by using the first vapor deposition film and the second vapor deposition film.

Note that the opening group forming region refers to a region located in the vapor deposition mask, and including the multiple openings and being larger than the display region of the active matrix substrate.

A method for producing a display device according to aspect 2 of the disclosure includes: forming a layered film by using a vapor deposition mask including one opening that vapor deposition particles pass through, and in the method, the one opening of the vapor deposition mask is larger than a display region of an active matrix substrate, in a third step of forming a third vapor deposition film on the active matrix substrate, the third vapor deposition film is formed in the display region of the active matrix substrate via a first portion of the one opening of the vapor deposition mask, and the third vapor deposition film is formed outside the display region of the active matrix substrate via a remaining second portion different from the first portion of the one opening of the vapor deposition mask, and in a fourth step of forming a fourth vapor deposition film on the active matrix substrate, the vapor deposition mask is shifted in one direction, a layered film including the third vapor deposition film and the fourth vapor deposition film is formed in the display region of the active matrix substrate, and the fourth vapor deposition film is formed outside the display region of the active matrix substrate such that the fourth vapor deposition film does not overlap with the third vapor deposition film formed outside the display region of the active matrix substrate in the third step.

In accordance with the above-described method, since the fourth vapor deposition film can be formed outside the display region of the active matrix substrate such that the fourth vapor deposition film does not overlap with the third vapor deposition film formed outside the display region of the active matrix substrate in the third step, film thickness variation and film formation positional offset can be inspected at high precision by using the third vapor deposition film and the fourth vapor deposition film.

In aspect 3 of the disclosure, in the method for producing a display device according to aspect 1, a pitch between the first openings adjacent to each other in the direction of shifting the vapor deposition mask is preferably the same as a pitch between the first opening and the second opening adjacent to each other in the direction of shifting the vapor deposition mask.

In accordance with the above-described method, film thickness variation and film formation positional offset can be inspected at high precision.

In aspect 4 of the disclosure, in the method for producing a display device according to aspect 1 or 3, the second opening group may be disposed at least on each of opposing sides of the first opening group to sandwich the first opening group between the second opening groups.

In accordance with the above-described method, a degree of freedom in the direction of shifting the vapor deposition mask, that is, a degree of freedom in the direction in which the vapor deposition mask is offset can be increased.

In aspect 5 of the disclosure, in the method for producing a display device according to any of aspects 1, 3 and 4, the vapor deposition mask may include third openings, the third openings may be disposed outside the first opening group and the second opening group, in the first step, the first vapor deposition film may be formed outside the display region of the active matrix substrate via the third openings, and in the second step, the second vapor deposition film may be formed outside the display region of the active matrix substrate via the third openings such that the second vapor deposition film does not overlap with the first vapor deposition film outside the display region of the active matrix substrate in the first step.

In accordance with the above-described method, for example, even after a protection film is formed near the display region, film thickness variation and film formation positional offset can be inspected at high precision.

In aspect 6 of the disclosure, in the method for producing a display device according to aspect 2, the vapor deposition mask may include third openings, the third openings may be disposed outside the one opening, in the third step, the third vapor deposition film may be formed outside the display region of the active matrix substrate via the third openings, and in the fourth step, the fourth vapor deposition film may be formed outside the display region of the active matrix substrate via the third openings such that the fourth vapor deposition film does not overlap with the third vapor deposition film outside the display region of the active matrix substrate in the third step.

In accordance with the above-described method, for example, even after a protection film is formed near the display region, film thickness variation and film formation positional offset can be inspected at high precision.

In aspect 7 of the disclosure, the method for producing a display device according to any of aspects 1, 3, 4 and 5 may include, between the first step and the second step, measuring a film thickness or positional offset of the vapor deposition film by using the first vapor deposition film formed outside the display region of the active matrix substrate.

In accordance with the above-described method, film thickness variation and film formation positional offset can be inspected at high precision between the first step and the second step.

In aspect 8 of the disclosure, the method for producing a display device according to any of aspects 1, 3, 4, 5 and 7 may include, after the second step, measuring a film thickness or positional offset of the vapor deposition film by using the second vapor deposition film formed outside the display region of the active matrix substrate.

In accordance with the above-described method, film thickness variation and film formation positional offset can be inspected at high precision after the second step.

In aspect 9 of the disclosure, the method for producing a display device according to any of aspects 1, 3, 4 and 5 may include, after the second step, measuring a film thickness or positional offset of the vapor deposition film by using the first vapor deposition film and the second vapor deposition film formed outside the display region of the active matrix substrate.

In accordance with the above-described method, film thickness variation and film formation positional offset can be inspected at high precision after the second step.

In aspect 10 of the disclosure, the method for producing a display device according to aspect 2 or 6 may include, between the third step and the fourth step, measuring a film thickness or positional offset of the vapor deposition film by using the third vapor deposition film formed outside the display region of the active matrix substrate.

In accordance with the above-described method, film thickness variation and film formation positional offset can be inspected at high precision between the third step and the fourth step.

In aspect 11 of the disclosure, the method for producing a display device according to any of aspects 2, 6 and 10 may include, after the fourth step, measuring a film thickness or positional offset of the vapor deposition film by using the fourth vapor deposition film formed outside the display region of the active matrix substrate.

In accordance with the above-described method, film thickness variation and film formation positional offset can be inspected at high precision after the fourth step.

In aspect 12 of the disclosure, the method for producing a display device according to aspect 2 or 6 may include, after the fourth step, measuring a film thickness or positional offset of the vapor deposition film by using the third vapor deposition film and the fourth vapor deposition film formed outside the display region of the active matrix substrate.

In accordance with the above-described method, film thickness variation and film formation positional offset can be inspected at high precision after the fourth step.

In aspect 13 of the disclosure, in the method for producing a display device according to any of aspects 1, 3, 4, 5, 7, 8 and 9, the first vapor deposition film may include a hole transport layer, and the second vapor deposition film may include a light emitting layer.

In accordance with the above-described method, film thickness variation and film formation positional offset of the hole transport layer and the light emitting layer can be inspected at high precision.

In aspect 14 of the disclosure, in the method for producing a display device according to any of aspects 2, 6, 10, 11 and 12, the third vapor deposition film may include a hole injection layer, and the fourth vapor deposition film may include an electron transport layer.

In accordance with the above-described method, film thickness variation and film formation positional offset of the hole injection layer and the electron transport layer can be inspected at high precision.

A vapor deposition mask according to aspect 15 of the disclosure includes multiple openings that vapor deposition particles pass through and that are disposed in accordance with a fixed rule, and in the vapor deposition mask, a size of an opening group forming region in which the multiple openings are formed is larger than a size of a display region of an active matrix substrate.

In accordance with the above-described configuration, since in the vapor deposition mask, the size of the region in which the multiple openings are formed is larger than the size of the display region of the active matrix substrate, unlayered vapor deposition films can be formed outside the display region of the active matrix substrate by shifting the vapor deposition mask in one direction to form multiple vapor deposition films. Therefore, the vapor deposition films enabling highly precise inspection of film thickness variation and film formation positional offset can be formed.

Note that the opening group forming region refers to a region located in the vapor deposition mask, and including the multiple openings and being larger than the display region of the active matrix substrate.

A vapor deposition mask according to aspect 16 of the disclosure includes one opening that vapor deposition particles pass through, and in the vapor deposition mask, a size of one opening is larger than a size of a display region of an active matrix substrate.

In accordance with the above-described configuration, since in the vapor deposition mask, the size of the one opening is larger than the size of the display region of the active matrix substrate, unlayered vapor deposition films can be formed outside the display region of the active matrix substrate by shifting the vapor deposition mask in one direction to form multiple vapor deposition films. Therefore, the vapor deposition films enabling highly precise inspection of film thickness variation and film formation positional offset can be formed.

In aspect 17 of the disclosure, in the vapor deposition mask according to aspect 15, openings disposed in the display region of the active matrix substrate among the multiple openings of the vapor deposition mask may constitute a first opening group, and openings disposed outside the display region of the active matrix substrate among the multiple openings of the vapor deposition mask may constitute a second opening group, and the second opening group may be disposed at least on each of opposing sides of the first opening group to sandwich the first opening group between the second opening groups.

In accordance with the above-described configuration, a degree of freedom in the direction of shifting the vapor deposition mask, that is, a degree of freedom in the direction in which the vapor deposition mask is offset can be increased.

In aspect 18 of the disclosure, in the vapor deposition mask according to aspect 15 or 17, openings disposed in the display region of the active matrix substrate among the multiple openings of the vapor deposition mask preferably constitute a first opening group, openings disposed outside the display region of the active matrix substrate among the multiple openings of the vapor deposition mask preferably constitute a second opening group, and a pitch between the first openings adjacent to each other in one direction of the first opening group is preferably the same as a pitch between the first opening of the first opening group and the second opening of the second opening group adjacent to each other in the one direction.

In accordance with the above-described configuration, the vapor deposition films enabling highly precise inspection of film thickness variation and film formation positional offset can be formed.

In aspect 19 of the disclosure, the vapor deposition mask according to any of aspects 15, 17 and 18 may include third openings disposed outside the multiple openings.

In accordance with the above-described configuration, for example, even after a protection film is formed near the display region, film thickness variation and film formation positional offset can be inspected at high precision.

In aspect 20 of the disclosure, the vapor deposition mask according to aspect 16 may include third openings disposed outside the one opening.

In accordance with the above-described configuration, for example, even after a protection film is formed near the display region, film thickness variation and film formation positional offset can be inspected at high precision.

An active matrix substrate according to aspect 21 of the disclosure includes a substrate, multiple active elements disposed on the substrate and multiple first electrodes disposed on the substrate and electrically connected to each of the multiple active elements, and in the active matrix substrate, a region in which the multiple first electrodes are formed includes a display region, a layered film including a hole transport layer and a light emitting layer is formed on each of the multiple first electrodes in the display region, and the hole transport layer and the light emitting layer are formed as a single layer outside the display region.

In accordance with the above-described configuration, since the hole transport layer and the light emitting layer are formed as a single layer outside the display region of the active matrix substrate, film thickness variation and film formation positional offset of the hole transport layer and the light emitting layer can be inspected at high precision.

In aspect 22 of the disclosure, in the active matrix substrate according to aspect 21, the layered film may include a hole injection layer and an electron transport layer, and the hole injection layer and the electron transport layer may be formed as a single layer outside the display region.

In accordance with the above-described configuration, film thickness variation and film formation positional offset of the hole injection layer and the electron transport layer can be inspected at high precision.

### Appendix

The disclosure is not limited to each of the embodiments described above, and various modifications can be implemented within the scope of the claims. Embodiments obtained by appropriately combining the technical approaches disclosed in the respective different embodiments also fall within the technical scope of the disclosure. Further, novel technical features can be formed by combining the technical approaches disclosed in the respective embodiments.

### INDUSTRIAL APPLICABILITY

The disclosure can be utilized for a method for producing a display device such as an organic EL display device, a vapor deposition mask and an active matrix substrate.

### REFERENCE SIGNS LIST

1 Organic EL display device
2 Substrate
3 Active element
4 Insulating film
5 First electrode
6 Hole injection layer
7R Hole transport layer
7G Hole transport layer
7B Hole transport layer
8R Red light emitting layer
8G Green light emitting layer
8B Blue light emitting layer
9 Electron transport layer
10 Edge cover
11 Vapor deposition mask
11a Vapor deposition mask
11b Vapor deposition mask
12 Opening group forming region
13R First opening
13R′ First opening group
13G First opening
13G′ First opening group
13B First opening
13W First opening group
14R Second opening
14R′ Second opening group
14G Second opening
14G′ Second opening group
14B Second opening
14W Second opening group
15 Third opening
20 Active matrix substrate
21 Single layer vapor deposition film
22 Layered film
23 Single layer vapor deposition film
24 Vapor deposition film for inspection
25 Vapor deposition film for inspection
30a Vapor deposition mask
30b Vapor deposition mask
31 Vapor deposition mask
31b Vapor deposition mask
31c Vapor deposition mask
41 Layered film
41′ Layered film
42 Single layer vapor deposition film
43 Single layer vapor deposition film
44 Vapor deposition film for inspection
45 Vapor deposition film for inspection
51 Layered film
51′ Layered film
52 Single layer vapor deposition film
53 Single layer vapor deposition film
54 Vapor deposition film for inspection
55 Vapor deposition film for inspection
61 Layered film
61′ Layered film
62 Single layer vapor deposition film
63 Single layer vapor deposition film
64 Vapor deposition film for inspection
65 Vapor deposition film for inspection
70 Vapor deposition mask
71 Opening
72 Third opening
73 Single layer vapor deposition film
91 Vapor deposition mask
92 Frame
92a Opening
93 Divided mask
L One side in a boundary of a first opening group
L′ One side in a boundary of a first opening group
DA Display region
PA Protection film forming region

1. A method for producing a display device, the method comprising:
forming a layered film by using a vapor deposition mask including multiple openings that vapor deposition particles pass through and that are disposed in accordance with a fixed rule,
wherein in the vapor deposition mask, a size of an opening group forming region in which the multiple openings are formed is larger than a size of a display region of an active matrix substrate,
in a first step of forming a first vapor deposition film on the active matrix substrate, the first vapor deposition film is formed in the display region of the active matrix substrate via a first opening group including multiple first openings serving as part of the multiple openings of the vapor deposition mask, and the first vapor deposition film is formed outside the display region of the active matrix substrate via a second opening group including multiple second openings serving as remaining part of the multiple openings of the vapor deposition mask, and
in a second step of forming a second vapor deposition film on the active matrix substrate, the vapor deposition mask is shifted in a direction of disposing at least part of the second opening group in the display region of the active matrix substrate, a layered film of the first vapor deposition film and the second vapor deposition film is formed in the display region of the active matrix substrate, and the second vapor deposition film is formed outside the display region of the active matrix substrate such that at least part of the second vapor deposition film does not overlap with the first vapor deposition film formed outside the display region of the active matrix substrate in the first step.

2. A method for producing a display device, the method comprising:
forming a layered film by using a vapor deposition mask including one opening that vapor deposition particles pass through,
wherein the one opening of the vapor deposition mask is larger than a display region of an active matrix substrate,
in a third step of forming a third vapor deposition film on the active matrix substrate, the third vapor deposition film is formed in the display region of the active matrix substrate via a first portion of the one opening of the vapor deposition mask, and the third vapor deposition film is formed outside the display region of the active matrix substrate via a remaining second portion different from the first portion of the one opening of the vapor deposition mask, and
in a fourth step of forming a fourth vapor deposition film on the active matrix substrate, the vapor deposition mask is shifted in one direction, a layered film including the third vapor deposition film and the fourth vapor deposition film is formed in the display region of the active matrix substrate, and the fourth vapor deposition film is formed outside the display region of the active matrix substrate such that the fourth vapor deposition film does not overlap with the third vapor deposition film formed outside the display region of the active matrix substrate in the third step.

3. The method for producing a display device according to claim
wherein a pitch between the first openings adjacent to each other in the direction of shifting the vapor deposition mask is the same as a pitch between the first opening and the second opening adjacent to each other in the direction of shifting the vapor deposition mask.

4. The method for producing a display device according to claim 1,
wherein the second opening group is disposed at least on each of opposing sides of the first opening group to sandwich the first opening group between the second opening groups.

5. The method for producing a display device according to claim 1,
wherein the vapor deposition mask includes third openings,
the third openings are disposed outside the first opening group and the second opening group,
in the first step, the first vapor deposition film is formed outside the display region of the active matrix substrate via the third openings, and
in the second step, the second vapor deposition film is formed outside the display region of the active matrix substrate via the third openings such that the second vapor deposition film does not overlap with the first vapor deposition film outside the display region of the active matrix substrate in the first step.

6. The method for producing a display device according to claim 2,
wherein the vapor deposition mask includes third openings,
the third openings are disposed outside the one opening,
in the third step, the third vapor deposition film is formed outside the display region of the active matrix substrate via the third openings, and
in the fourth step, the fourth vapor deposition film is formed outside the display region of the active matrix substrate via the third openings such that the fourth vapor deposition film does not overlap with the third vapor deposition film outside the display region of the active matrix substrate in the third step.

7. The method for producing a display device according to claim 1, comprising, between the first step and the second step, measuring a film thickness or positional offset of the vapor deposition film by using the first vapor deposition film formed outside the display region of the active matrix substrate.

8. The method for producing a display device according to claim 1, comprising, after the second step, measuring a film thickness or positional offset of the vapor deposition film by using the second vapor deposition film formed outside the display region of the active matrix substrate.

9. The method for producing a display device according to claim 1, comprising, after the second step, measuring a film thickness or positional offset of the vapor deposition film by using the first vapor deposition film and the second vapor deposition film formed outside the display region of the active matrix substrate.

10. The method for producing a display device according to claim 2, comprising, between the third step and the fourth step, measuring a film thickness or positional offset of the vapor deposition film by using the third vapor deposition film formed outside the display region of the active matrix substrate.

11. The method for producing a display device according to claim 2, comprising, after the fourth step, measuring a film thickness or positional offset of the vapor deposition film by using the fourth vapor deposition film formed outside the display region of the active matrix substrate.

12. The method for producing a display device according to claim 2, comprising, after the fourth step, measuring a film thickness or positional offset of the vapor deposition film by using the third vapor deposition film and the fourth vapor deposition film formed outside the display region of the active matrix substrate.

13. The method for producing a display device according to claim 1,
wherein the first vapor deposition film includes a hole transport layer, and
the second vapor deposition film includes a light emitting layer.

14. The method for producing a display device according to claim 2,
wherein the third vapor deposition film includes a hole injection layer, and
the fourth vapor deposition film includes an electron transport layer.

15-22. (canceled)
